(19) United States
(12) Patent Application Publication
(10) Pub. No.: US 2007/0232047 A1
(43) Pub. Date: Oct. 4, 2007

(54) Damage recovery method for low K layer in a damascene interconnection

(76) Inventors: Masanaga Fukasawa, Fishkill, NY (US); Takeshi Nogami, Chappaqua, NY (US)

Correspondence Address: MAYER & WILLIAMS PC, 251 NORTH AVE. WEST, 2ND FLOOR, WESTFIELD, NJ, 07090, US

(21) Appl. No.: 11/395,829

(22) Filed: Mar. 31, 2006

(51) Int. Cl. H01L 21/44

(52) U.S. Cl. 438/597

(57) ABSTRACT

A method of fabricating a damascene interconnection is provided. The method begins by forming on a substrate a low k dielectric layer and a resist pattern over the low k dielectric layer to define a first interconnect opening. The low k dielectric layer is etched through the resist pattern to form the first interconnect opening, whereby damage arises to a portion of the low k dielectric layer defining a sidewall of the first interconnect opening. The resist pattern is then removed and a barrier layer is applied to line the first interconnect opening. An interconnection is formed by filling the first interconnect opening with a conductive material. The interconnection is planarized to remove excess material, whereby an underlying portion of the low k dielectric layer is damaged during planarizing. The damaged underlying portion of the low k dielectric layer and the damaged sidewall portion of the low k dielectric layer are both repaired at least in part after performing the planarizing step.

### FIELD OF THE INVENTION

The present invention relates generally to single and dual damascene interconnections for integrated circuits, and more specifically to a single or dual damascene interconnection having a porous low k layer.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD.

Recently, porous low k materials have been employed in damascene processes. A void-filled, or porous dielectric material has a lower dielectric constant than the fully dense void-free or nonporous version of the same material. Such porous low-dielectric constant materials may be deposited by chemical vapor deposition (CVD), or may be spun on in liquid solution and subsequently cured by heating to remove the solvent. Porous low-dielectric constant materials are advantageous in that they have a dielectric constant of 3.0 or less. Examples of such porous low-dielectric constant materials include porous SILK™ and porous silicon carbonated oxide, as examples. A porogen may be included in the porous low-dielectric constant materials to cause the formation of the pores.

Many of the porous low k materials, however, have properties that are incompatible with other materials employed to fabricate semiconductor devices or are incompatible with processes employed to fabricate the semiconductor devices. The very nature of the desirable porous structure of these materials also make them fragile and easily damaged by etching or Chemical Mechanical Polishing (CMP) processes. For example, layers formed from low dielectric materials are often structurally compromised by CMP processes when etching trenches or vias or planarizing a copper interconnect by etching, both of which can damage organic low k dielectric materials by the removal of carbon.

Accordingly, it would be desirable to provide a damascene interconnect structure in which damage that arises to low k dielectric materials from etching or CMP processes is largely repaired.

### SUMMARY OF THE INVENTION

In accordance with the present invention, a method of fabricating a damascene interconnection is provided. The method begins by forming on a substrate a low k dielectric layer and a resist pattern over the low k dielectric layer to define a first interconnect opening. The low k dielectric layer is etched through the resist pattern to form the first interconnect opening, whereby damage arises to a portion of the low k dielectric layer defining a sidewall of the first interconnect opening. The resist pattern is then removed and a barrier layer is applied to line the first interconnect opening. An interconnection is formed by filling the first interconnect opening with a conductive material. The interconnection is planarized to remove excess material, whereby an underlying portion of the low k dielectric layer is damaged during planarizing. The damaged underlying portion of the low k dielectric layer and the damaged sidewall portion of the low k dielectric layer are both repaired at least in part after performing the planarizing step.

In accordance with one aspect of the invention, the repair is performed by exposing the damaged portions to one or more chemical agents that replenish carbon into the damaged portions of the low k dielectric layers.

In accordance with another aspect of the invention, the repair is performed by diffusing carbon laterally through the damaged sidewall portion of the low k dielectric layer and through a thickness of the damaged underlying portion of the low k dielectric layer.

In accordance with another aspect of the invention, after replenishing carbon, excess solvent or other chemical agents is removed through a heating process.

In accordance with another aspect of the invention, a capping layer is deposited over the underlying portion of the low k dielectric layer after it has been repaired at least in part.

In accordance with another aspect of the invention, a capping layer is deposited on the low k dielectric layer and both the capping layer and the porous low k layer are etched through the resist pattern.

In accordance with another aspect of the invention, the low k dielectric has a dielectric constant between about 2.0 and 3.8.

In accordance with another aspect of the invention, the step of etching the low k dielectric layer is performed by Reactive Ion Etching (RIE).

In accordance with another aspect of the invention, the low k dielectric layer is a porous low k dielectric layer.

In accordance with another aspect of the invention, the porous low k dielectric layer includes SiLK™.

In accordance with another aspect of the invention, the low k dielectric layer includes SiOCH.

In accordance with another aspect of the invention, the first interconnect opening comprises a via.

In accordance with another aspect of the invention, the first interconnect opening comprises a via and a trench connected thereto.

In accordance with another aspect of the invention, the planarizing step is performed by CMP.

In accordance with another aspect of the invention, the damascene interconnection is a dual damascene interconnection.

In accordance with another aspect of the invention, a second resist pattern is formed over the capping layer and the low k dielectric layer is etched to form a second interconnect opening that is connected to the first interconnect opening, wherein both the first and second interconnect openings are filled with the conductive material.

In accordance with another aspect of the invention, the conductive material is copper.

In accordance with another aspect of the invention, an integrated circuit is provided having a damascene interconnection constructed in accordance any of the aforementioned methods.

### BRIEF DESCRIPTION OF THE DRAWINGS

FIGS. 1-11 show cross-sectional views illustrating the formation of a dual damascene structure constructed in accordance with one embodiment of the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. Via-first refers to the order in which the trench and via features are etched. For via-first, the via feature is etched through the entire thickness of the ILD before the trench feature is etched through a portion of the ILD thickness. Conversely, for trench-first, the trench feature is etched partially through the thickness of the ILD before the via feature is etched through the remaining ILD thickness at the base of the trench feature. While a via-first process will be illustrated, the present invention is also applicable to trench-first and other dual damascene processes as well as single damascene processes.

The present invention repairs in whole or in part the aforementioned damage that may be caused to low k dielectrics by plasma dry etching and CMP processes by the removal of carbon. As discussed in more detail below, in the present invention the damage is repaired by exposing the damaged portions of the low k dielectric material to carbon-containing chemical agents after the via and/or trench is formed, filled with conductive material and planarized.

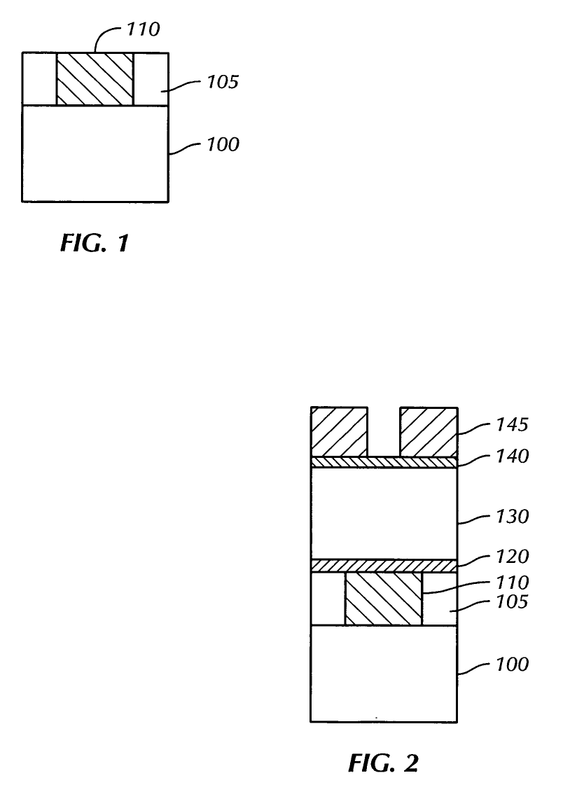

A method of fabricating dual damascene interconnections according to an embodiment of the present invention will now be described with reference to FIG. 1 through 12. Of course, the present invention is equally applicable to a single damascene interconnect structure.

As shown in FIG. 1, a substrate 100 is prepared. A lower ILD layer 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminum, and aluminum alloy. The lower interconnection 110 is preferably formed of copper because of its low resistance. Also, the surface of the lower interconnection 110 is preferably planarized.

Referring to FIG. 2, a barrier or etch stop layer 120, a low-k ILD layer 130, and a capping layer 140 are sequentially stacked on the surface of the substrate 100 where the lower interconnection 110 is formed, and a photoresist pattern 145 is formed on the capping layer 140 to define a via. It should be noted that capping layer 140 is optional and need not be employed in all embodiments of the invention.

The barrier or etch stop layer 120 is formed to prevent electrical properties of the lower interconnection 110 from being damaged during a subsequent etch process for forming a via. Accordingly, the etch stop layer 120 is formed of a material having a high etch selectivity with respect to the ILD layer 130 formed thereon. In one embodiment, the etch stop layer 120 is formed of SiC, SiN, or SiCN, having a dielectric constant of 4 to 5. The etch stop layer 120 is as thin as possible in consideration of the dielectric constant of the entire ILD layer, but thick enough to properly function as an etch stop layer.

The ILD layer 130 is formed of a low k material such as a porous dielectric material. Typically, the porous dielectric material comprises a porous low-k material having a dielectric constant (k) value of 3.0 or lower. In some cases the porous dielectric material may have a dielectric constant of less than about 2.5. For example, the porous dielectric material may comprise a material having a k value of about 3.0 or less with a porogen introduced in order form pores, which lowers the dielectric constant to 2.7 or less, and more preferably about 2.5 or less, e.g. 1.8 or 1.9. Typically, the more pores formed in the material, the lower the dielectric constant k of the dielectric material will be. The ILD layer 130 may have a thickness of few thousand angstroms for example. Alternatively, the porous dielectric material may comprise other thicknesses. The porous dielectric material may be selected from a wide range of materials, including, without limitation, comprise porous methylsilsesquioxane (MSQ), porous inorganic materials, porous CVD materials, porous organic materials, or combinations thereof.

One widely used approach that can be employed to form porous low k materials relies on the incorporation of a thermally degradable material (porogen) within a host thermosetting matrix. Upon heating, the matrix material crosslinks, and the porogen undergoes phase separation from the matrix to form nanoscopic domains. Subsequent heating leads to porogen decomposition and diffusion of the volatile by-products out of the matrix. Under optimized processing conditions, a porous network results in which the pore size directly correlates with the original phase-separated morphology. Two commercially available materials of this type are Dow Chemical's porous SiLK and IBM's DendriGlass materials.

Dendriglass is a chemical composition containing MSQ and various amounts of a second phase polymeric material, i.e. a pore-forming agent. Dendriglass can be made into a porous film with a dielectric constant in a range between about 1.3 and about 2.6 depending on the amount of the second phase material added to the film. The second phase polymeric material, or the pore-forming agent, is a material that is usually a long chained polymer which can be decomposed and volatilized and driven from the matrix material, i.e. MSQ, after the film has been cured in a first curing process. Dendriglass can be spin-coated and then cured at a temperature of less than about 350° C. Finally, the structure is heated to a temperature higher than the first temperature, or preferably higher than about 400° C. to 450° C., for a time period long enough to drive out the second phase polymeric material from the Dendriglass resulting in a porous low-k dielectric film.

Referring again to FIG. 2, after formation of the porous ILD layer 130, capping layer 140 is formed thereabove. The capping layer 140 prevents the porous ILD layer 130 from being damaged when damascene interconnections are planarized using chemical mechanical polishing (CMP). The capping layer 140 also serves as a hardmask during the subsequent etching steps used to form vias and trenches. The capping layer 140 may be formed of any appropriate material such as SiO₂, SiOF, SiON, SiCOH, SiC, SiN, or SiCN. For example, in conventional processes an organosilicon compound such as tetraethoxysilane (TEOS) is used to form an SiO₂ capping layer by PECVD. As previously mentioned, the capping layer 140 must generally be sufficient thick to prevent damage to the underlying ILD layer 130 during subsequent CMP processing. Unfortunately, the dielectric constant of the capping layer 140 is generally greater than the dielectric constant of the ILD layer 130, thereby increasing the overall capacitance of the structure and for this reason should be kept as thin as possible if it is to remain a part of the final structure. In the example presented below, however, the capping layer 140 is ultimately removed.

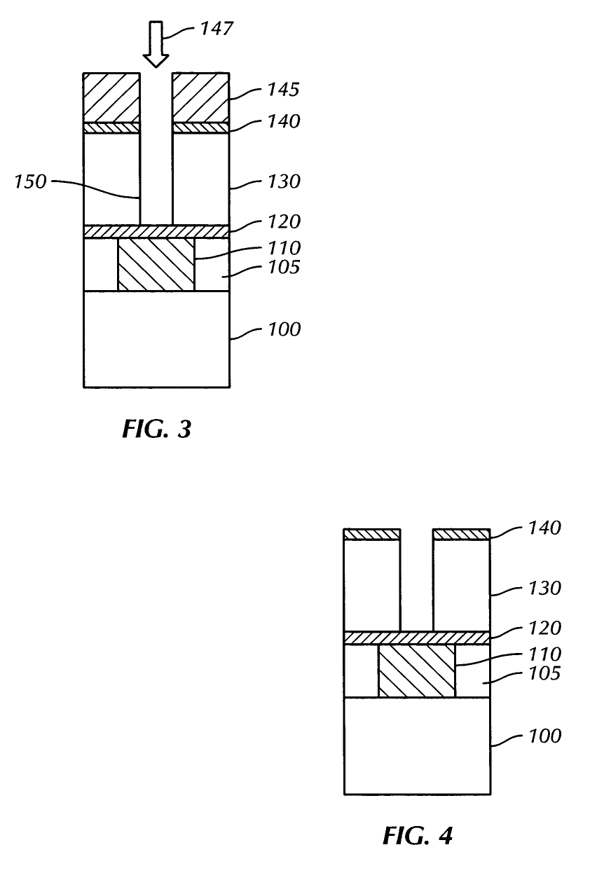

After formation of porous ILD layer 130 and capping layer 140, the process continues by forming the via photoresist pattern 145 by depositing a layer of a photoresist and then performing exposure and developing processes using a photo mask defining a via. Referring to FIG. 3, the ILD layer 130 is anisotropically etched (147) using the photoresist pattern 145 as an etch mask to form a via 150. The ILD layer 130 can be etched, for example, using a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COX. Here, the RIE conditions are adjusted such that only the porous ILD layer 130 is selectively etched and the etch stop layer 120 is not etched.

Referring to FIG. 4, the via photoresist pattern 145 is removed using a stripper. If the photoresist pattern 145 is removed using O₂-ashing, which is widely used for removing a photoresist pattern, the ILD layer 130, which often contains carbon, may be damaged by the O₂-based plasma. Thus, the photoresist pattern 145 alternatively may be removed using an H₂-based plasma. In some cases, the via 150 is filled with a back filling material (not shown) such as an organic polymer that is spin-coated and baked. The back-filling material, which serves to protect the shape of the via while the trench is etched, is subsequently removed, for example, by an oxygen plasma.

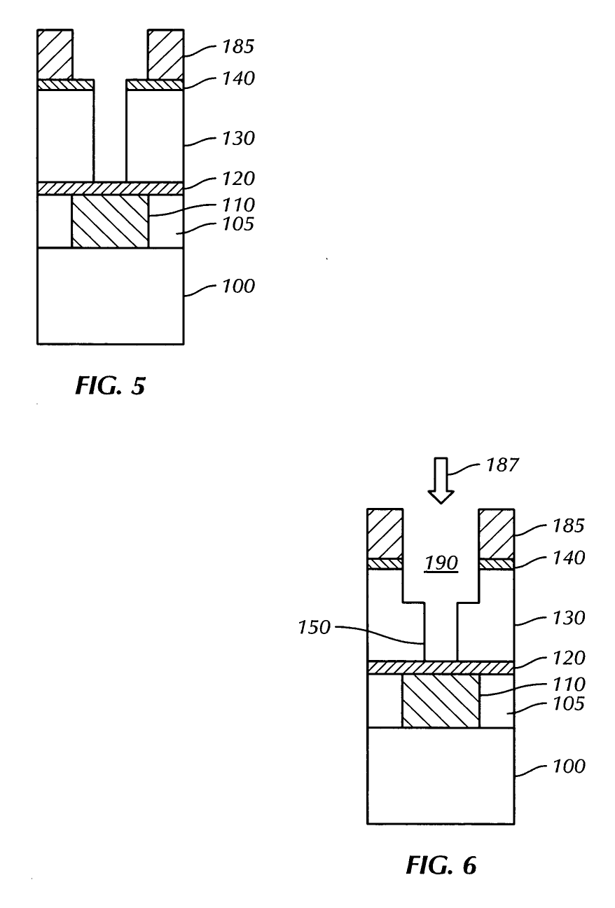

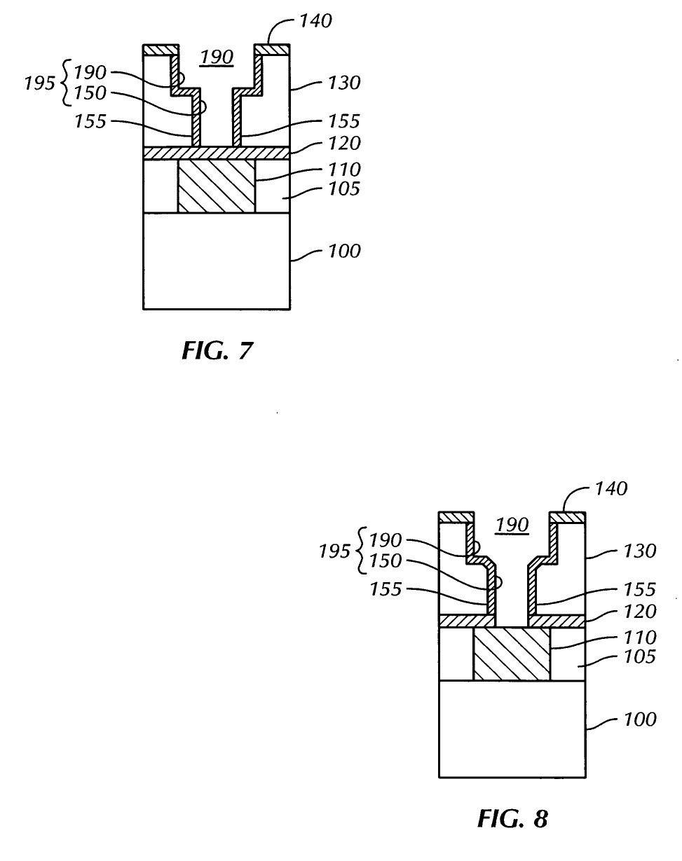

Referring to FIG. 5, a trench photoresist pattern 185 is formed, followed by formation of a trench 190 in FIG. 6. The capping layer 140 is etched using the photoresist pattern 185 as an etch mask, and then the ILD layer 130 is etched (187) to a predetermined depth to form the trench 190. The resulting structure, shown in FIG. 7, defines a dual damascene interconnection region 195, which includes the via 150 and the trench 190.

As previously mentioned, during the plasma etching as well as photoresist removal, significant damage occurs to the low-k materials of which ILD layer 130 is composed (represented in FIG. 7 by damaged regions 155), which causes carbon depletion from the low-k material adjacent to the etched sidewalls of the trench 190 and via 150. In addition to a higher effective k, the resultant structures are susceptible to void formation, outgassing and blister formation. The voids in turn may cause an increase in leakage current at elevated voltages and reduction in breakdown voltage. As further explained below, the present invention describes a way to reduce the damage and resulting issues by treating the low k materials after the damage is caused.

Continuing the process with reference to FIG. 8, the etch stop layer 120 exposed in the via 150 is etched until the lower interconnection 110 is exposed, thereby completing the dual damascene interconnection region 195. The etch stop layer 120 is etched so that the lower interconnection 110 is not affected and only the etch stop layer 120 is selectively removed.

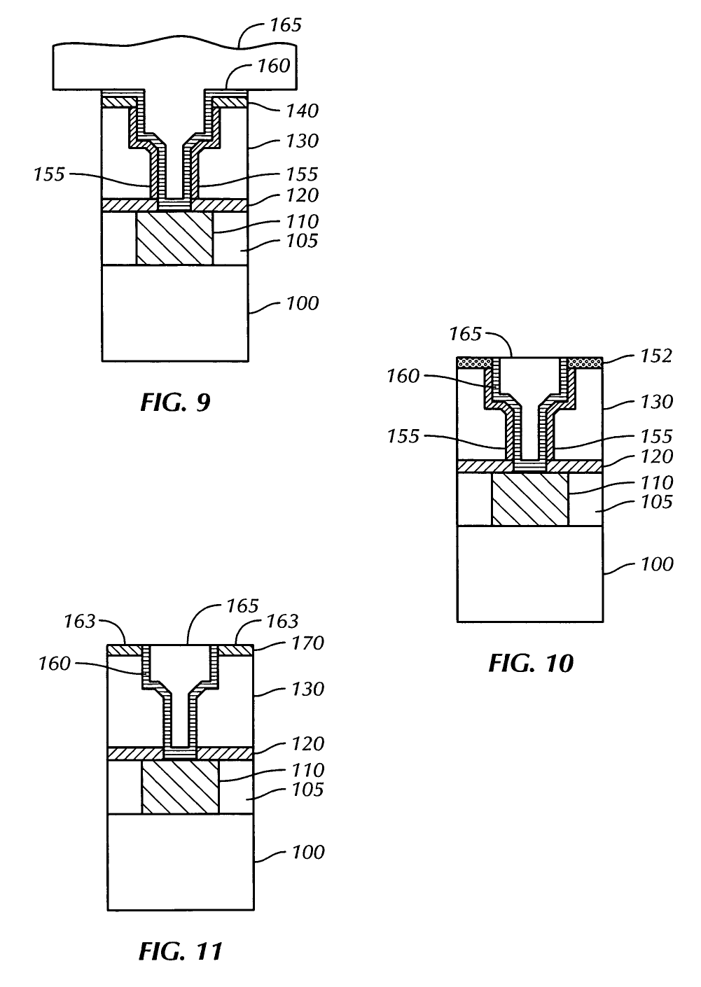

A barrier layer 160 is formed on the dual damascene interconnection region 195 (as well as capping layer 140) to prevent the subsequently formed conductive layer from diffusing into ILD layer 130. The barrier layer 160 is generally formed from a conventional material such as tantalum, tantalum nitride, titanium, titanium silicide, ruthenium or zirconium. After formation of the barrier layer 160 a copper seed layer (not shown) is formed, which is required for the subsequent deposition of bulk copper. That is, copper electroplating occurs on top of the copper seed layer. Referring to FIG. 9, the bulk copper layer 165 is formed on the dual damascene interconnection region 195. The excess metal and barrier material above the interconnects is then removed by chemical mechanical polishing (CMP), thereby forming the dual damascene interconnection shown in FIG. 10. The CMP process involves introducing a chemical slurry to the surface of the ILD while using a rotating polishing pad to remove excess metal and planarize the surface of the ILD.

More specifically, in a CMP process, the structure is positioned on a CMP pad located on a platen or web. A force is then applied to press the structure against the CMP pad. The CMP pad and the structure are moved against and relative to one another while applying the force to polish and planarize the surface. A polishing solution, often referred to as polishing slurry, is dispensed on the CMP pad to facilitate the polishing. The polishing slurry typically contains an abrasive and is chemically reactive to selectively remove the unwanted material, for example, the metal and barrier layers, more rapidly than other materials, for example, a dielectric material.

As previously noted, the capping layer 140 is provided to prevent damage to the ILD layer 130 during the CMP process. If the capping layer is too thin or not present, significant damage may occur to the underlying ILD layer during CMP processing. Similar to the damage caused to the trench and via sidewalls by etching, such damage to the underlying ILD layer may cause, for example, fluorine addition and carbon depletion from the porous low-k material adjacent to the etched surface. Once again, in addition to a higher effective k, the resultant structures are susceptible to void formation, outgassing and blister formation, thereby potentially causing an increase in leakage current at elevated voltages and a reduction in breakdown voltage. As shown in FIG. 10, the portion of ILD layer 130 that is damaged by the CMP process is represented by damaged regions 152.

In accordance with the present invention, the damaged regions 152 and 155 can be repaired at the same time (i.e., in the same process treatment step or steps) by replenishing the carbon that has been removed. The treatment results in replenishment of carbon to the low-k film, thereby restoring hydrophobicity, lowering the dielectric constant, and providing resistance to further damage such as during a wet cleaning operation. The damage repair treatment is conducted by exposing the structure to an appropriate chemical agent or agents in liquid or gas form for a period sufficient to complete the reaction with the damaged low-k regions 152 and 155. Other contemplated techniques for exposing the structure to the chemical agent or agents includes vapor exposure (with or without plasma), spin coating and the use of supercritical fluids such as supercritical CO₂. (Supercritical fluids or solutions exist when the temperature and pressure of a solution are above its critical temperature and pressure. In this state, there is no differentiation between the liquid and gas phases and the fluid is referred to as a dense gas in which the saturated vapor and saturated liquid states are identical. Due to their high density, low viscosity and negligible surface tension, supercritical fluids possess superior solvating properties.) Finally, after the structure has been sufficiently exposed to the chemical agent or agents by the appropriate means, a high temperature bake can be performed to remove any remaining solvent and excess chemical agents.

One example of a suitable chemical agent is commercially available under the tradename Toughening Agent™, which is available from Honeywell. This a liquid agent that is spin-coated and baked so that the solvent evaporates and carbon is replenished. For this particular agent baking may be performed between about 300C to 400C for 30 minutes to one hour. Alternatively, the structure may be exposed to a gas such as TMCTS for 10 minutes at temperatures between about 300C to 400C, for example.

The damage repair treatment requires the chemical agent or agents to diffuse throughout the damaged regions 152 and 155. As evident from FIG. 10, the diffusion originates largely from the top surface of damaged region 152 and not through the sidewalls of the trench and via because of the presence of the bulk copper layer 165 as well as barrier layer 160. While the thickness of the damaged region 152 through which the agents must diffuse is not unduly great (generally on the order of a few hundred angstroms), the situation for damaged region 155 is quite a bit different. Since the chemical agent or agents must diffuse through the damaged layer 155 a distance that roughly corresponds to the distance from the upper surface of damaged layer 152 to the top of etch stop layer 120, the diffusion process can be problematic. This distance, generally about a few thousand angstroms, is an order of magnitude greater than the diffusion depth required to penetrate the damaged region 152 alone. It has been shown, for instance, that the hydrophobicity of damaged low k materials can be restored by the use of silylation processes using conventional silylation agents or other common monofunctional agents. In particular, as shown in S. V. Nitta et al., Use of Difunctional Silylation Agents for Enhanced Repair of Post Plasma Damaged Porous Low K Dielectrics, in Advanced Metallization Conference 2005 (pp 325-331), published by Material Research Society, the effectiveness of the silylation reaction depends on the dissociation energy of the leaving group, the size of the molecule, the pore size of the dielectric material, and the medium in which the silylation is performed.

After the damaged ILD layers 152 and 155 have been repaired a capping layer may be deposited over the surface, which in FIG. 11 is designated by capping layer 163. Capping layer 163 may be formed from any appropriate material such as SiC or the other materials mentioned above in connection with capping layer 140.

In the embodiments of the invention discussed above both ILD layers 152 and 155 are repaired after performing CMP processing. In some embodiments of the invention, however, the ILD layer 155 may be repaired before the ILD layer 152. For instance, the ILD layer 155 may be repaired before the conductive material 165 is deposited, whereas the ILD layer 152 may be repaired after the conductive material 165 has been deposited and planarized.

Although various embodiments are specifically illustrated and described herein, it will be appreciated that modifications and variations of the present invention are covered by the above teachings and are within the purview of the appended claims without departing from the spirit and intended scope of the invention. For example, those of ordinary skill in the art will recognize that the via-first dual damascene process described with reference to FIGS. 1 through 11 can be applied to a trench-first dual damascene process.

1. A method of fabricating a damascene interconnection, the method comprising:
(a) forming on a substrate a low k dielectric layer;
(b) forming a resist pattern over the low k dielectric layer to define a first interconnect opening;
(c) etching the low k dielectric layer through the resist pattern to form the first interconnect opening, whereby damage arises to a portion of the low k dielectric layer defining a sidewall of the first interconnect opening;
(d) removing the resist pattern;
(e) applying a barrier layer to line the first interconnect opening;
(f) forming an interconnection by filling the first interconnect opening with a conductive material;
(g) planarizing the interconnection to remove excess material whereby an underlying portion of the low k dielectric layer is damaged during planarizing;
(h) repairing at least in part both the damaged underlying portion of the low k dielectric layer and the damaged sidewall portion of the low k dielectric layer after performing the planarizing of step (g).

2. The method of claim 1 wherein the repairing is performed by exposing the damaged portions to one or more chemical agents that replenish carbon into the damaged portions of the low k dielectric layers.

3. The method of claim 1 wherein the repairing is performed by diffusing carbon laterally through the damaged sidewall portion of the low k dielectric layer and through a thickness of the damaged underlying portion of the low k dielectric layer.

4. The method of claim 1 further comprising, after replenishing carbon, removing excess solvent or other chemical agents through a heating process.

5. The method of claim 1 further comprising depositing a capping layer over the underlying portion of the low k dielectric layer after it has been repaired at least in part.

6. The method of claim 1 further comprising forming a capping layer on the low k dielectric layer and in step (c) etching the capping layer and the porous low k layer through the resist pattern.

7. The method of claim 1 wherein the low k dielectric has a dielectric constant between about 2.0 and 3.8.

8. The method of claim 1 wherein the step of etching the low k dielectric layer is performed by Reactive Ion Etching (RIE).

9. The method of claim 1 wherein the low k dielectric layer is a porous low k dielectric layer.

10. The method of claim 9 wherein the porous low k dielectric layer includes SiLK™.

11. The method of claim 1 wherein the low k dielectric layer includes SiOCH.

12. The method of claim 1 wherein the first interconnect opening comprises a via.

13. The method of claim 1 wherein the first interconnect opening comprises a via and a trench connected thereto.

14. The method of claim 1 wherein the planarizing step (g) is performed by CMP.

15. The method of claim 6 wherein the damascene interconnection is a dual damascene interconnection and further comprising the steps of applying a second resist pattern over the capping layer and etching the low k dielectric layer to form a second interconnect opening that is connected to said first interconnect opening and wherein the step of forming the first and second interconnect openings includes filling the first and second interconnect openings with the conductive material.

16. The method of claim 1 wherein the conductive material is copper.

17. An integrated circuit having a damascene interconnection constructed in accordance with the method of claim 1.

18. A method of fabricating a damascene interconnection, the method comprising:
(a) forming on a substrate a low k dielectric layer;
(b) forming a resist pattern over the low k dielectric layer to define a first interconnect opening;
(c) etching the low k dielectric layer through the resist pattern to form the first interconnect opening, whereby damage arises to a portion of the low k dielectric layer defining a sidewall of the first interconnect opening;
(d) removing the resist pattern;
(e) applying a barrier layer to line the first interconnect opening;
(f) forming an interconnection by filling the first interconnect opening with a conductive material;
(g) planarizing the interconnection to remove excess material whereby an underlying portion of the low k dielectric layer is damaged during planarizing;
(h) repairing at least in part both the damaged underlying portion of the low k dielectric layer and the damaged sidewall portion of the low k dielectric layer.

19. The method of claim 18 wherein the step of repairing at least in part both the damaged underlying portion of the low k dielectric layer and the damaged sidewall portion of the low k dielectric layer after performing the planarizing of step (g).

20. The method of claim 18 wherein the step of repairing the damaged sidewall portion of the low k dielectric layer is performed before repairing the damaged underlying portion of the low k dielectric layer.

21. The method of claim 18 wherein the step of repairing the damaged sidewall portion of the low k dielectric layer is performed before filling the first interconnect opening with a conductive material.
